(19) United States
(12) Patent Application Publication
(10) Pub. No.: US 2026/0243950 A1
(43) Pub. Date: Aug. 20, 2026

(54) WHITE LASER LIGHT SYNTHESIS APPARATUS BASED ON QUANTUM DOT PHOTON LANTERN STRUCTURE AND METHOD FOR PREPARING SAME

(71) Applicant: CHANGCHUN INSTITUTE OF OPTICS, FINE MECHANICS AND PHYSICS, CHINESE ACADEMY OF SCIENCES, CHANGCHUN (CN)

(72) Inventors: Hongbo ZHU, CHANGCHUN (CN); Xingchen LIN, CHANGCHUN (CN); Pengcheng WAN, CHANGCHUN (CN); Chenhui ZHANG, CHANGCHUN (CN); Yawei ZHANG, CHANGCHUN (CN); Xulan XUE, CHANGCHUN (CN); Huidan ZHANG, CHANGCHUN (CN); Yongqiang NING, CHANGCHUN (CN); Lijun WANG, CHANGCHUN (CN)

(73) Assignee: CHANGCHUN INSTITUTE OF OPTICS, FINE MECHANICS AND PHYSICS, CHINESE ACADEMY OF SCIENCES, CHANGCHUN (CN)

(21) Appl. No.: 19/542,962

(22) Filed: Feb. 18, 2026

(30) Foreign Application Priority Data
Feb. 18, 2025 (CN) 202510174204.5

(51) Int. Cl. G02B 6/10

(52) U.S. Cl. CPC G02B 6/102

(57) ABSTRACT

A white laser light synthesis apparatus based on a quantum dot photon lantern structure and a method for preparing same. The apparatus includes a first few-mode quartz optical fiber, a quantum dot photon lantern, and a second few-mode quartz optical fiber. The first few-mode quartz optical fiber receives input laser light. The first few-mode quartz optical fiber is connected to one end of the quantum dot photon lantern such that the quantum dot photon lantern receives the input laser light and is excited by the input laser light to form red light, green light, and blue light. The second few-mode quartz optical fiber is connected to the other end of the quantum dot photon lantern such that the second few-mode quartz optical fiber receives the red light, green light, and blue light, combines the three light beams to form white light, and outputs the white light.

### CROSS-REFERENCE TO RELATED APPLICATION

The application claims priority to Chinese patent application No. 202510174204.5, filed on February 18, 2025, the entire contents of which are incorporated herein by reference.

### TECHNICAL FIELD

The present disclosure belongs to the technical field of laser semiconductors, and in particular relates to a white laser light synthesis apparatus based on a quantum dot photon lantern structure and a method for preparing same.

### BACKGROUND

White laser light based on the synthesis of multiple monochromatic light beams possesses advantages such as high conversion efficiency and good color rendering index, making it one of the ideal next-generation light sources for illumination and display. White laser light boasts advantages such as small size, long lifespan, stable performance, and good color rendering index at the same time, and has broad application prospects in the fields of laser illumination and laser display. Conventional optical fiber-based synthesis of white laser light typically involves coupling red, green, and blue laser beams separately into an optical fiber and then combining the multiple laser beams, thereby combining the light beams of three primary colors into white laser light. In this process, multiple different monochromatic light sources are required, and each of the different monochromatic light beams needs to be modulated separately so as to achieve an optimal ratio. Therefore, there is an urgent need for a novel white light synthesis apparatus whose structure can effectively simplify white laser light synthesis apparatuses and provide a new option for white light synthesis technology.

### SUMMARY

In view of the foregoing, the present disclosure aims to provide a white laser light synthesis apparatus based on a quantum dot photon lantern structure and a method for preparing same. The apparatus incorporates colloidal quantum dots capable of generating red light, blue light and green light into a photon lantern, simplifying conventional optical fiber-based white laser light synthesis methods, and allowing for obtaining satisfactory white laser light simply by passing a light beam into a quantum dot lantern where splitting of the light beam and combination of the split beams are performed.

In order to achieve the foregoing aim, technical solutions of the present disclosure are realized as follows: A white laser light synthesis apparatus based on a quantum dot photon lantern structure, comprising: a first few-mode quartz optical fiber configured to receive input laser light; a quantum dot photon lantern, the first few-mode quartz optical fiber being configured to connect to one end of the quantum dot photon lantern such that the quantum dot photon lantern receives the input laser light and is excited by the input laser light to form red light, green light, and blue light; and a second few-mode quartz optical fiber configured to connect to the other end of the quantum dot photon lantern such that the second few-mode quartz optical fiber receives the red light, green light, and blue light, combines the three light beams to form white light, and outputs the white light.

Further, the quantum dot photon lantern comprises multiple single-mode fibers in which colloidal quantum dots are injected; the multiple single-mode optical fibers are divided into three groups according to the type of the colloidal quantum dots contained therein, such that the input laser light enters the three groups of single-mode optical fibers respectively and the red light, green light, and blue light are formed correspondingly.

Further, the first few-mode quartz optical fiber, the second few-mode quartz optical fiber and the single-mode optical fibers have a core diameter in the range of from 4 μm to 10 μm.

Further, the input laser light has a wavelength in the range of from 300 nm to 400 nm, the red light has a wavelength in the range of from 620 nm to 720 nm, the blue light has a wavelength in the range of from 450 nm to 495 nm, and the green light has a wavelength in the range of from 495 nm to 570 nm.

A method for preparing a white laser light synthesis apparatus based on a quantum dot photon lantern structure, comprising: S1: preparing a hollow photon lantern, a first few-mode quartz optical fiber and a second few-mode quartz optical fiber; S2: preparing colloidal quantum dots that generate red light, green light, and blue light respectively; S3: injecting the colloidal quantum dots obtained in step S2 into the hollow photon lantern obtained in step S1, and curing the hollow photon lantern and the colloidal quantum dots contained therein to obtain a quantum dot photon lantern; and S4: welding both ends of the quantum dot photon lantern obtained in step S3 to the first few-mode quartz optical fiber and the second few-mode quartz optical fiber prepared in step S1, respectively, thereby obtaining the white laser light synthesis apparatus.

Further, in step S1, multiple hollow single-mode optical fibers are divided into three groups, closely arranged, and inserted into an outer sheath to form the hollow photon lantern, the three groups of hollow single-mode optical fibers corresponding to the colloidal quantum dots of red light, green light, and blue light, respectively.

Further, in step S1, the process of preparing the first few-mode quartz optical fiber or the second few-mode quartz optical fiber comprises: closely arranging multiple hollow single-mode optical fibers to form a bound bundle, inserting the bound bundle into an outer sheath to form a pre-fabricated optical fiber bundle, and performing a melting and tapering operation on the pre-fabricated optical fiber bundle to form the first few-mode quartz optical fiber or the second few-mode quartz optical fiber; the end of the first few-mode quartz optical fiber or the second few-mode quartz optical fiber subjected to melting and tapering is a few-mode end, and the other end is a single-mode end.

Further, in step S4, the two ends of each of the single-mode optical fibers in the quantum dot photon lantern are correspondingly welded to the single-mode end of the first few-mode quartz optical fiber and the single-mode end of the second few-mode quartz optical fiber, respectively.

Further, in step S2, the three kinds of colloidal quantum dots have different quantum dot materials and quantum dot diameters.

Further, in step S2, the three kinds of colloidal quantum dots have the same quantum dot material and quantum dot diameter, and the three kinds of colloidal quantum dots are prepared at different temperatures.

Compared with the prior art, the present disclosure can achieve the following beneficial effects: The white laser light synthesis apparatus based on a quantum dot photon lantern structure and the method for preparing same according to the present disclosure incorporates a white light synthesis technology with a quantum dot photon lantern. Laser passing through a tapered region of the photon lantern is split into multiple laser beams. The laser beams pass through multiple kinds of quantum dots having different dimensions and different concentrations and undergo absorption and transition, whereby red light, green light, and blue light of other wave bands are formed. Then the red light, green light, and blue light are combined to obtain a beam of standard white laser. The apparatus enables obtaining satisfactory white laser light simply by passing a light beam into the apparatus where splitting of the light beam and combination of the split beams are performed. As such, a more simplified synthesis apparatus is introduced for the white laser light synthesis technology.

### BRIEF DESCRIPTION OF DRAWINGS

The accompanying drawings that constitute part of the present disclosure are intended to provide a further understanding of the present disclosure. Illustrative examples and explanations thereof of the present disclosure are intended to explain the present disclosure, and do not constitute an improper limitation on the present disclosure. In the drawings:

FIG. 1 is a schematic structural diagram of a white laser light synthesis apparatus based on a quantum dot photon lantern structure according to an example of the present disclosure; and

FIG. 2 is a schematic flow chart of a preparation method for preparing a white laser light synthesis apparatus based on a quantum dot photon lantern structure according to an example of the present disclosure.

### Explanations of reference numerals

1. first few-mode quartz optical fiber; 2. quantum dot photon lantern; 3. second few-mode quartz optical fiber; 4. colloidal quantum dots; 5. single-mode optical fibers; 6. few-mode end; 7. single-mode end.

### DETAILED DESCRIPTION OF THE EMBODIMENTS

In order to make the objects, technical solutions, and advantages of the present disclosure clearer and more understandable, the present disclosure will be further explained in detail in conjunction with the accompanying drawings and specific examples. It should be understood that the specific examples described herein are solely for the purpose of explaining the present disclosure, and do not constitute a limitation on the present disclosure.

It should be noted that the examples of the present disclosure and the features in the examples can be combined with each other, provided that there is no conflict.

In the description of the present disclosure, it should be understood that an orientational or positional relationship indicated by terms such as “central”, “longitudinal”, “transverse”, “upper”, “lower”, “front”, “rear”, “left”, “right”, “vertical”, “horizontal”, “top”, “bottom”, “inner”, and “outer” is the orientational or positional relationship shown based on the drawings, and is merely for the convenience of describing the present disclosure and simplifying the description, rather than indicating or implying that an apparatus or unit referred to must have a particular orientation or must be constructed and operated in a particular orientation. Therefore, the terms should be understood as a limitation on the present disclosure. In addition, terms such as “first” and “second” are merely used for the purpose of description and should not be understood as indicating or implying relative importance or implicitly indicating the number of a technical feature referred to. A feature defined by “first”, “second”, etc. may explicitly or implicitly include one or more items of the feature. In the description of the present disclosure, unless otherwise specified, “multiple” means two or more items.

In the description of the present disclosure, it should be noted that unless otherwise definitely specified and limited, the term “installed”, “joined”, or “connected” should be broadly understood. For example, it may refer to fixedly connected, detachably connected, or integrally connected; alternatively, it may refer to mechanically connected or electrically connected; alternatively, it may refer to connected directly, or indirectly via an intermediate medium; alternatively, it may refer to interconnection of interiors of two units. For a person of ordinary skill in the art, the specific meaning of the foregoing terms in the present disclosure can be understood depending on specific situations.

The present disclosure will be explained in detail below with reference to the drawings and in conjunction with examples.

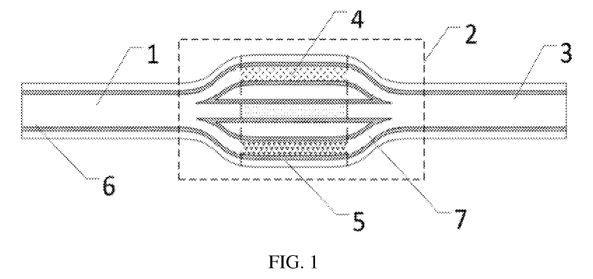

As shown in FIG. 1, the white laser light synthesis apparatus based on a quantum dot photon lantern structure according to examples of the present disclosure comprises a first few-mode quartz optical fiber 1, a quantum dot photon lantern 2, and a second few-mode quartz optical fiber 3. The first few-mode quartz optical fiber 1 is configured to receive input laser light. The first few-mode quartz optical fiber 1 is connected to one end of the quantum dot photon lantern 2 such that the quantum dot photon lantern 2 receives the input laser light and is excited by the input laser light to form red light, green light, and blue light. The second few-mode quartz optical fiber 3 is connected to the other end of the quantum dot photon lantern 2 such that the second few-mode quartz optical fiber 3 receives the red light, green light, and blue light, combines the three light beams to form white light, and outputs the white light.

In some examples, the quantum dot photon lantern comprises multiple single-mode fibers 5 in which colloidal quantum dots 4 are injected. The multiple single-mode optical fibers 5 are divided into three groups according to the type of the colloidal quantum dots contained therein, such that the input laser light enters the three groups of single-mode optical fibers respectively, and the red light, green light, and blue light correspondingly.

In one specific example, the quantum dot photon lantern comprises three single-mode fibers 5 in which the colloidal quantum dots 4 are injected. The three single-mode fibers 5 are configured to form the red light, green light, and blue light correspondingly.

In some examples, the first few-mode quartz optical fiber 1, the second few-mode quartz optical fiber 3 and the single-mode optical fibers 5 have a core diameter in the range of from 4 μm to 10 μm. In one specific example, the first few-mode quartz optical fiber 1, the second few-mode quartz optical fiber 3 and the single-mode optical fibers 5 have a core diameter of 8 μm.

In some examples, the input laser light has a wavelength in the range of from 300 nm to 400 nm, the red light has a wavelength in the range of from 620 nm to 720 nm, the blue light has a wavelength in the range of from 450 nm to 495 nm, and the green light has a wavelength in the range of from 495 nm to 570 nm.

In one specific example, input laser light of 360 nm, after being subjected to phase modulation, is coupled into the first few-mode quartz optical fiber 1 and conveyed to the quantum dot photon lantern 2, where it is split into three beams. The three beams of the input laser light pass through respective corresponding colloidal quantum dots and undergo absorption and transition, whereby red light of 650 nm, green light of 532 nm, and blue light of 450 nm are formed, with the light-splitting ratio of red light to green light to blue light being 0.477:0.334:0.189. The red light, green light, and blue light are combined by the second few-mode optical fiber 3, from which standard white laser light having a color temperature approaching 6500 K is outputted.

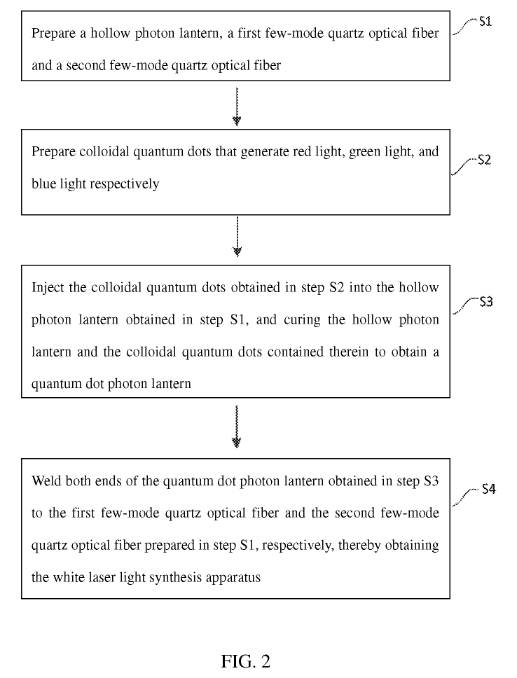

A method for preparing a white laser light synthesis apparatus based on a quantum dot photon lantern structure is provided, as shown in FIG. 1 and FIG. 2, which comprises: S1: preparing a hollow photon lantern, a first few-mode quartz optical fiber 1 and a second few-mode quartz optical fiber 3.

In some examples, multiple hollow single-mode optical fibers are divided into three groups, closely arranged, and inserted into an outer sheath to form the hollow photon lantern, the three groups of hollow single-mode optical fibers corresponding to the colloidal quantum dots of red light, green light, and blue light, respectively. The process of preparing the first few-mode quartz optical fiber 1 or the second few-mode quartz optical fiber 3 comprises: closely arranging multiple hollow single-mode optical fibers to form a bound bundle, inserting the bound bundle into an outer sheath to form a pre-fabricated optical fiber bundle, and performing a melting and tapering operation on the pre-fabricated optical fiber bundle to form the first few-mode quartz optical fiber 1 or the second few-mode quartz optical fiber 3. The end of the first few-mode quartz optical fiber 1 or the second few-mode quartz optical fiber 3 subjected to melting and tapering is a few-mode end 6, and the other end is a single-mode end 7.

In one specific example, three hollow single-mode optical fibers are closely arranged and inserted into an outer sheath to form the hollow photon lantern, the three hollow single-mode optical fibers corresponding to the colloidal quantum dots of red light, green light, and blue light, respectively. The process of preparing the first few-mode quartz optical fiber 1 or the second few-mode quartz optical fiber 3 comprises: closely arranging three hollow single-mode optical fibers to form a bound bundle, inserting the bound bundle into an outer sheath to form a pre-fabricated optical fiber bundle, and performing a melting and tapering operation on the pre-fabricated optical fiber bundle to form the first few-mode quartz optical fiber 1 or the second few-mode quartz optical fiber 3. The end of the first few-mode quartz optical fiber 1 or the second few-mode quartz optical fiber 3 subjected to melting and tapering is the few-mode end 6, and the other end is the single-mode end 7. One end of the respective three hollow single-mode optical fibers is retained in the single-mode end 7.

S2: preparing colloidal quantum dots that generate red light, green light, and blue light respectively.

In some examples, the three kinds of colloidal quantum dots have different quantum dot materials and quantum dot diameters.

In one specific examples, CsPbI_{1.5}Br_{1.5} perovskite quantum dots having an initial mass concentration of 8 mg/ml are dissolved into toluene solvent and are shaken in an ultrasonic cleaner for 5 min such that the quantum dots are mixed evenly. Then the mixed solution is mixed with a PS (polystyrene) adhesive to obtain colloidal quantum dots corresponding to red light. Similarly, CsPbBr₃ perovskite quantum dots having an initial mass concentration of 10 mg/ml and CsPbBr_{1.5}Cl_{1.5} perovskite quantum dots having an initial mass concentration of 8 mg/ml are dissolved into toluene solvent, ultrasonically shaken, and mixed with the PS adhesive in the same manner, thereby obtaining colloidal quantum dots corresponding to blue light and green light respectively. The three kinds of prepared colloidal quantum dots are stored in a light-proof sealed environment. White lights of different color temperatures are obtained by adjusting the doping proportions of the colloidal quantum dots and the dimension of the quantum dots and modulating the power of the red light, blue light, and green light.

In some examples, the three kinds of colloidal quantum dots have the same quantum dot material and quantum dot diameter, and the three kinds of colloidal quantum dots are prepared at different temperatures.

In one specific example, the quantum dot material in the three kinds of colloidal quantum dots may be cadmium selenide (PbTe), copper indium sulfur (CuInS₂), silver indium sulfur (AgInS₂), or an alternative material at the same time. The conversion wavelength of laser light can be changed by adjusting the preparation temperature of the colloidal quantum dots to generate red light, blue light, and green light.

S3: injecting the colloidal quantum dots obtained in step S2 into the hollow photon lantern obtained in step S1, and curing the hollow photon lantern and the colloidal quantum dots contained therein to obtain a quantum dot photon lantern.

In one specific example, the three kinds of colloidal quantum dots are injected into corresponding hollow single-mode optical fibers by means of a mechanical pump. Upon completion of volatilization of the toluene component of the PS adhesive in the three kinds of colloidal quantum dot materials, three single-mode optical fibers 5 doped with colloidal quantum dots are obtained. In this process, care should be taken such that no impurities and bubbles can be present inside the three kinds of doped colloidal quantum dots during filling. Upon completion of curing, it is found by transmission scanning electron microscopy analysis that in the three single-mode optical fibers 5, the CsPbI_{1.5}Br_{1.5} perovskite quantum dots have a diameter of 14 nm, the CsPbBr₃ perovskite quantum dots have a diameter of 12 nm, and the CsPbBr_{1.5}Cl_{1.5} perovskite quantum dots have a diameter of 10 nm.

S4: welding both ends of the quantum dot photon lantern obtained in step S3 to the first few-mode quartz optical fiber and the second few-mode quartz optical fiber prepared in step S1, respectively, thereby obtaining the white laser light synthesis apparatus.

In some examples, the two ends of each of the single-mode optical fibers 5 in the quantum dot photon lantern 2 are correspondingly welded to the single-mode end 7 of the first few-mode quartz optical fiber 1 and the single-mode end 7 of the second few-mode quartz optical fiber 3, respectively, as shown in FIG. 1, in which the position of dotted lines represents the position of welding, so as to ensure that laser light enters the quantum dot photon lantern 2 from the few-mode end 6 of the first few-mode quartz optical fiber 1 and ultimately exits from the few-mode end 6 of the second few-mode quartz optical fiber 3.

It should be understood various forms of processes shown above can be used to reorder, add, or delete steps. For example, the steps described in the present disclosure can be implement in parallel, in sequence or in different orders. As long as expected results of the technical solutions of the present disclosure can be achieved, no limitation is made herein.

The above specific embodiments do not constitute any limitation on the scope of protection of the present disclosure. Those skilled in the art should understand that various modifications, combinations, sub-combinations and substitutions can be made according to design requirements and other factors. Any modification, equivalent replacement and improvement made within the spirit and principle of the present disclosure shall be included in the scope of protection of the present disclosure.

What is claimed is:

1. A white laser light synthesis apparatus based on a quantum dot photon lantern structure, comprising:
a first few-mode quartz optical fiber configured to receive input laser light;
a quantum dot photon lantern, the first few-mode quartz optical fiber being configured to connect to one end of the quantum dot photon lantern such that the quantum dot photon lantern receives the input laser light and is excited by the input laser light to form red light, green light, and blue light; and
a second few-mode quartz optical fiber configured to connect to the other end of the quantum dot photon lantern such that the second few-mode quartz optical fiber receives the red light, green light, and blue light, combines the three light beams to form white light, and outputs the white light.

2. The white laser light synthesis apparatus based on a quantum dot photon lantern structure according to claim 1, wherein
the quantum dot photon lantern comprises multiple single-mode fibers in which colloidal quantum dots are injected;
the multiple single-mode optical fibers are divided into three groups according to the type of the colloidal quantum dots contained therein, such that the input laser light enters the three groups of single-mode optical fibers respectively, and the red light, green light, and blue light are formed correspondingly.

3. The white laser light synthesis apparatus based on a quantum dot photon lantern structure according to claim 2, wherein the first few-mode quartz optical fiber, the second few-mode quartz optical fiber and the single-mode optical fibers have a core diameter in the range of from 4 μm to 10 μm.

4. The white laser light synthesis apparatus based on a quantum dot photon lantern structure according to claim 1, wherein the input laser light has a wavelength in the range of from 300 nm to 400 nm, the red light has a wavelength in the range of from 620 nm to 720 nm, the blue light has a wavelength in the range of from 450 nm to 495 nm, and the green light has a wavelength in the range of from 495 nm to 570 nm.

5. A method for preparing a white laser light synthesis apparatus based on a quantum dot photon lantern structure, the method comprising:
S1: preparing a hollow photon lantern, a first few-mode quartz optical fiber and a second few-mode quartz optical fiber;
S2: preparing colloidal quantum dots that generate red light, green light, and blue light respectively;
S3: injecting the colloidal quantum dots obtained in step S2 into the hollow photon lantern obtained in step S1, and curing the hollow photon lantern and the colloidal quantum dots contained therein to obtain a quantum dot photon lantern; and
S4: welding both ends of the quantum dot photon lantern obtained in step S3 to the first few-mode quartz optical fiber and the second few-mode quartz optical fiber prepared in step S1, respectively, thereby obtaining the white laser light synthesis apparatus.

6. The method for preparing a white laser light synthesis apparatus based on a quantum dot photon lantern structure according to claim 5, wherein in step S1, multiple hollow single-mode optical fibers are divided into three groups, closely arranged, and inserted into an outer sheath to form the hollow photon lantern, the three groups of hollow single-mode optical fibers corresponding to the colloidal quantum dots of red light, green light, and blue light, respectively.

7. The method for preparing a white laser light synthesis apparatus based on a quantum dot photon lantern structure according to claim 5, wherein in step S1, the process of preparing the first few-mode quartz optical fiber or the second few-mode quartz optical fiber comprises:
closely arranging multiple hollow single-mode optical fibers to form a bound bundle, inserting the bound bundle into an outer sheath to form a pre-fabricated optical fiber bundle, and performing a melting and tapering operation on the pre-fabricated optical fiber bundle to form the first few-mode quartz optical fiber or the second few-mode quartz optical fiber;
the end of the first few-mode quartz optical fiber or the second few-mode quartz optical fiber subjected to melting and tapering is a few-mode end, and the other end is a single-mode end.

8. The method for preparing a white laser light synthesis apparatus based on a quantum dot photon lantern structure according to claim 7, wherein in step S4, the two ends of each of the single-mode optical fibers in the quantum dot photon lantern are correspondingly welded to the single-mode end of the first few-mode quartz optical fiber and the single-mode end of the second few-mode quartz optical fiber, respectively.

9. The method for preparing a white laser light synthesis apparatus based on a quantum dot photon lantern structure according to claim 5, wherein in step S2, the three kinds of colloidal quantum dots have different quantum dot materials and quantum dot diameters.

10. The method for preparing a white laser light synthesis apparatus based on a quantum dot photon lantern structure according to claim 5, wherein in step S2, the three kinds of colloidal quantum dots have the same quantum dot material and quantum dot diameter, and the three kinds of colloidal quantum dots are prepared at different temperatures.
